(19) United States
(12) Patent Application Publication
(10) Pub. No.: US 2009/0163003 A1
(43) Pub. Date: Jun. 25, 2009

(54) MANUFACTURING METHOD OF SELF-SEPARATION LAYER

(76) Inventors: Chien-Chung FU, Hsinchu City (TW); Hao-Chung KUO, Hsinchu City (TW); Cheng-Huan CHEN, Hsinchu City (TW)

Correspondence Address: Muncy, Geissler, Olds & Lowe, PLLC, P.O. BOX 1364, FAIRFAX, VA, 22038-1364, US

(21) Appl. No.: 12/336,253

(22) Filed: Dec. 16, 2008

(30) Foreign Application Priority Data
Dec. 20, 2007 (TW) 096149043

(51) Int. Cl. H01L 21/20

(52) U.S. Cl. 438/507; 257/E21.09

(57) ABSTRACT

A manufacturing method of a self separation layer includes the steps of: forming a plurality of convex portions on a substrate; growing a main material layer on the convex portions; and separating the main material layer from the substrate.

This application claims priority of No. 096149043 filed in Taiwan R.O.C. on Dec. 20, 2007 under 35 USC 119, the entire content of which is hereby incorporated by reference.

### BACKGROUND OF THE INVENTION

1. Field of Invention

The invention relates to a manufacturing method of a self separation layer, and more particularly to a manufacturing method of a self separation layer without the use of the laser lift-off technology so that the cost of the laser lift-off step and the poor influence generated by the thermal stress can be reduced.

2. Related Art

Light sources, which become more and more popular, include a light-emitting diode and a laser diode. The light-emitting diode is a cold lighting element for releasing the energy, which is generated when electrons and holes in the semiconductor material are combined together, in the form of light. Different mono-chromatic light rays with different wavelengths may be outputted according to different properties of the used materials. The light-emitting diodes may be mainly classified into a visible light light-emitting diode and an invisible light (e.g., infrared or ultra-violet ray) light-emitting diode. Compared with the conventional light bulb or lamp, the light-emitting diode advantageously has the power-saving property, the vibration resistant property, the long lifetime and the high flickering speed, so the light-emitting diode has become the indispensable element in the daily life. On the other hand, the laser diode is mainly adapted to the optical communication and optical storage devices.

The basic light-emitting diode includes a substrate, a buffer layer formed on the substrate, an N-type semiconductor layer formed on the buffer layer, an active layer partially covering the N-type semiconductor layer, a P-type semiconductor layer formed on the active layer, and two contact electrode layers respectively formed on the two semiconductor layers.

The active layer of the conventional light-emitting diode has the high dislocation density so that the internal quantum efficiency of the light-emitting diode is decreased, the light-emitting luminance thereof is decreased, the heat is generated and the temperature of the light-emitting diode is increased. In addition, the light rays outputted from the active layer travel toward many directions, and the light rays outputted toward the backlight surface are absorbed by the substrate so that the light-emitting efficiency is decreased.

When a conventional blue diode is being manufactured, a sapphire substrate usually serves as an epitaxy substrate. Then, a nitride semiconductor layer and other nitride compounds are formed on the epitaxy substrate and then an element is manufactured. Next, the element is lifted off the epitaxy substrate by the laser lift-off technology. Thus, the cost of the overall procedures is very high, and the procedures are time-consuming and labor-consuming. In addition, the active layer may have the thermal damage and the thermal stress remained therein due to the heat generated during the machining process so that the optical and electric efficiency of the element is deteriorated.

Thus, it is an important subject of the invention to provide a manufacturing method of a self separation layer with a lower dislocation density and without using the laser lift-off technology.

### SUMMARY OF THE INVENTION

It is therefore an object of the invention to provide a manufacturing method of a self separation layer with a lower epitaxy dislocation density of an active layer and without using the laser lift-off technology. Thus, the light-emitting efficiency of a light source formed using this self separation layer can be enhanced.

To achieve the object, the invention provides a manufacturing method of a self separation layer. The method includes the steps of: forming a plurality of convex portions on a substrate; growing a main material layer on the convex portions; and separating the main material layer from the substrate.

The step of forming the convex portions may include the sub-steps of: forming an auxiliary material layer on the substrate; forming a metal layer on the auxiliary material layer; annealing the metal layer to form a plurality of metal particles on the auxiliary material layer; etching the auxiliary material layer with the metal particles serving as a mask to form the convex portions; and removing the metal particles.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a flow chart showing a manufacturing method of a self separation layer according to the invention.

FIGS. 2A to 2C are schematic illustrations showing structures corresponding to various steps of the method of FIG. 1.

FIG. 3 is a flow chart showing the step S1 of FIG. 1.

FIGS. 4A to 4C are cross-sectional views showing structures corresponding to the sub-steps of FIG. 3.

FIGS. 5A and 5B show two examples of the main material layer.

### DETAILED DESCRIPTION OF THE INVENTION

The present invention will be apparent from the following detailed description, which proceeds with reference to the accompanying drawings, wherein the same references relate to the same elements.

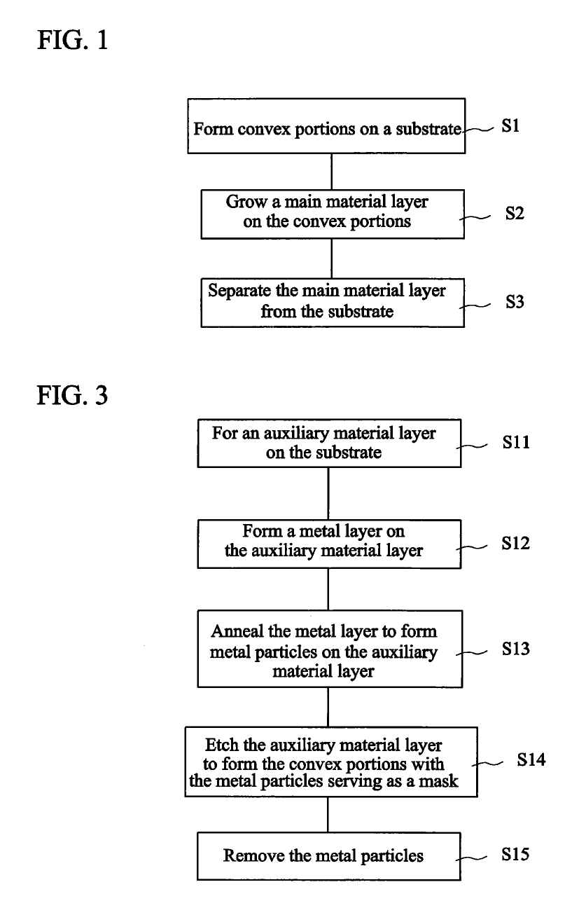

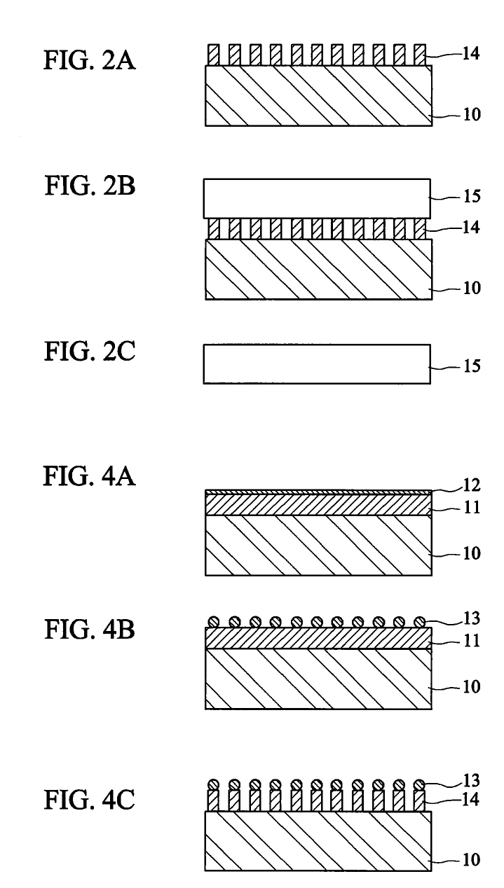

FIG. 1 is a flow chart showing a manufacturing method of a self separation layer according to the invention. FIGS. 2A to 2C are schematic illustrations showing structures corresponding to various steps of the method of FIG. 1. The manufacturing method of the self separation layer of the invention will be described with reference to FIGS. 1 and 2A to 2C.

First, in step S1, a plurality of convex portions 14 is formed on a substrate 10, as shown in FIG. 2A. In this embodiment, the substrate 10 is a sapphire substrate. The material of the substrate 10 may also be selected from the group consisting of silicon, silicon carbide, magnesium oxide, arsenide, phosphide and zinc oxide.

Next, in step S2, a main material layer 15 is grown on the convex portions 14, as shown in FIG. 2B. The main material layer 15 is composed of the nitride semiconductor material (GaN or AlN). The main material layer 15 is grown on the convex portions 14 by way of hydride vapor phase epitaxy (HVPE) or metalorganic chemical vapor deposition (MOCVD). Because only the convex portions 14 contact with the substrate 10 and the overall surface of the main material layer 15 is not combined with the substrate 10, the dislocation density of the grown main material layer 15 can be effectively reduced.

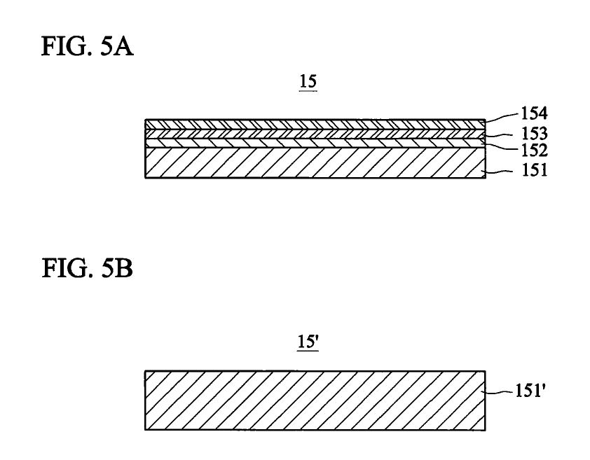

Then, in step S3, the main material layer 15 is separated from the substrate 10, as shown in FIG. 2C. The main material layer 15 is the required lighting element, or may serve as an element substrate on which other elements may be formed, wherein the details thereof will be described later with reference to FIGS. 5A and 5B.

There are many methods of manufacturing the convex portions 14, and one of the methods will be described in the following. FIG. 3 is a flow chart showing the step S1 of FIG. 1. FIGS. 4A to 4C are cross-sectional views showing structures corresponding to the sub-steps of FIG. 3.

First, in steps S11 and S12, an auxiliary material layer 11 is formed on the substrate 10. Than, a metal layer 12 is formed on the auxiliary material layer 11. At this time, the structure is shown in FIG. 4A. The auxiliary material layer 11 is composed of the nitride semiconductor material, such as gallium nitride or aluminum nitride (GaN or AIN). For example, the material of the metal layer 12 is gold, copper, aluminum, nickel, cobalt, iron, an iron/cobalt metal compound or a nickel/cobalt metal compound, and the metal layer 12 may be formed by way of evaporation, plating or any other suitable method.

Then, in step S13, the metal layer 12 is annealed to form a plurality of metal particles 13 on the auxiliary material layer 11, as shown in FIG. 4B.

Next, in step S14, the auxiliary material layer 11 is etched to form the plurality of convex portions 14 with the metal particles 13 serving as a mask, as shown in FIG. 4C. In this embodiment, each convex portion 14 is a rod-like body having a diameter smaller than one micron. That is, the convex portion 14 has the nanometer-level dimension. Alternatively, the diameter of each rod-like body is smaller than several microns, such as three microns. The auxiliary material layer 11 may be etched through to reach the substrate 10. Alternatively, the auxiliary material layer 11 having the very small thickness may also be remained.

Then, in step S15, the metal particles 13 are removed, as shown in FIG. 2A.

The auxiliary material layer 11 and the main material layer 15 are made of the same material. Alternatively, the material of the auxiliary material layer 11 is a seed material for growing the main material layer 15. The substrate 10 and the auxiliary material layer 11 have different coefficients of thermal expansion. So, after the main material layer 15 is completely grown and is moved out of an epitaxy reactor, the convex portions 14 are broken and thus lifted off the substrate 10 due to the difference between the coefficients of thermal expansion. Because the main material layer 15 is self-separated after been grown, this layer is referred to as a self separation layer.

FIGS. 5A and 5B show two examples of the main material layer. Referring to FIG. 5A, the main material layer 15 includes an element substrate 151, a first-type semiconductor layer 152, an active layer 153 and a second-type semiconductor layer 154. The first-type semiconductor layer 152, such as a P/N type semiconductor layer, is disposed on an element substrate 151. The active layer 153 is disposed on the first-type semiconductor layer 152. The second-type semiconductor layer 154, such as the N/P type semiconductor layer, is disposed on the active layer 153. Thus, the step of growing the main material layer 15 includes the following sub-steps. First, the element substrate 151 is grown on the convex portions 14. Next, the first-type semiconductor layer 152 is formed on the element substrate 151. Then, the active layer 153 is formed on the first-type semiconductor layer 152. Finally, the second-type semiconductor layer 154 is formed on the active layer 153.

As shown in FIG. 5B, the main material layer 15′ is composed of a single element substrate 151′. That is, the main material layer 15′ serves as an element substrate on which other elements can be formed.

The dislocation density of the main material layer 15 can be reduced. So, the light-emitting efficiency and luminance of the light-emitting diode device formed using this main material layer 15 may be effectively enhanced. In addition, this method can bring the effect of automatically separating the main material layer from the substrate without the additional laser lift-off procedure. In addition, the substrate can be effectively recycled and reused so that the environment protective requirement is satisfied and the additional economic effectiveness may be provided.

While the invention has been described by way of examples and in terms of preferred embodiments, it is to be understood that the invention is not limited thereto. To the contrary, it is intended to cover various modifications. Therefore, the scope of the appended claims should be accorded the broadest interpretation so as to encompass all such modifications.

What is claimed is:

1. A manufacturing method of a self separation layer, comprising the steps of:
(a) forming a plurality of convex portions on a substrate;
(b) growing a main material layer on the convex portions; and
(c) separating the main material layer from the substrate.

2. The method according to claim 1, wherein a material of the substrate is selected from the group consisting of silicon, silicon carbide, magnesium oxide, arsenide, phosphide, zinc oxide and sapphire.

4. The method according to claim 1, wherein each of the convex portions is a rod-like body.

5. The method according to claim 4, wherein a diameter of each of the rod-like body is smaller than one micron.

6. The method according to claim 1, wherein the main material layer is grown on the convex portions by way of hydride vapor phase epitaxy (HVPE) or metalorganic chemical vapor deposition (MOCVD).

7. The method according to claim 1, wherein the step of forming the convex portions comprises the sub-steps of:
(a1) forming an auxiliary material layer on the substrate;
(a2) forming a metal layer on the auxiliary material layer;
(a3) annealing the metal layer to form a plurality of metal particles on the auxiliary material layer;
(a4) etching the auxiliary material layer with the metal particles serving as a mask to form the convex portions; and
(a5) removing the metal particles.

8. The method according to claim 7, wherein the auxiliary material layer is composed of a nitride semiconductor.

9. The method according to claim 7, wherein the auxiliary material layer and the main material layer are formed of the same material.

10. The method according to claim 7, wherein a material of the auxiliary material layer serves as a seed material for growing the main material layer.

11. The method according to claim 7, wherein the substrate and the auxiliary material layer have different coefficients of thermal expansion so that the convex portions are broken due to a difference between the coefficients of thermal expansion of the substrate and the auxiliary material layer.

12. The method according to claim 7, wherein a material of the metal layer comprises gold, copper, aluminum, nickel, cobalt, iron, a iron/cobalt metal compound or a nickel/cobalt metal compound.

13. The method according to claim 7, wherein the metal layer is formed by way of evaporation or plating.

14. The method according to claim 7, wherein in the sub-step (a4), the auxiliary material layer is etched through to reach the substrate.

15. The method according to claim 4, wherein a diameter of the rod-like body is smaller than three microns.

16. The method according to claim 1, wherein the main material layer is composed of a single element substrate.

17. The method according to claim 1, wherein the main material layer comprises:
an element substrate;
a first-type semiconductor layer disposed on the element substrate;
an active layer disposed on the first-type semiconductor layer; and
a second-type semiconductor layer disposed on the active layer.

18. The method according to claim 1, wherein the step (b) comprises the sub-steps of:
(b1) forming an element substrate on the convex portions;
(b2) forming a first-type semiconductor layer on the element substrate;
(b3) forming an active layer on the first-type semiconductor layer; and
(b4) forming a second-type semiconductor layer on the active layer.
